(19) United States
(12) Patent Application Publication
(10) Pub. No.: US 2009/0206416 A1
(43) Pub. Date: Aug. 20, 2009

(54) DUAL METAL GATE STRUCTURES AND METHODS

(75) Inventors: Kangguo Cheng, Guilderland, NY (US); Keith Kwong Hon Wong, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 12/033,326

(22) Filed: Feb. 19, 2008

(51) Int. Cl. H01L 21/8238; H01L 27/092

(52) U.S. Cl. 257/369; 438/199; 257/E21.639; 257/E27.062

(57) ABSTRACT

Two dummy gate structures containing disposable material portions and metal portions, source and drain regions, and metal semiconductor alloy regions are formed on a semiconductor substrate. A dielectric material layer is deposited and planarized so that top surfaces of the two remaining dummy gate structures are substantially coplanar. A disposable material portion and a metal portion are removed from one dummy gate structure, while the other dummy gate structure is protected. Subsequently, another disposable material portion is removed from the other dummy gate structure. A second metal layer comprising a second metal is deposited and planarized to form two gate electrodes. One gate electrode has a gate dielectric abutting the first metal, while the other electrode has a gate electrode abutting the second metal. Both gate electrodes have substantially the same height since the two top surfaces of the gate electrodes are formed by the same planarization process.

### FIELD OF THE INVENTION

The present invention generally relates to semiconductor devices, and particularly to complementary metal-oxide-semiconductor (CMOS) devices having dual metal gate structures, and methods of manufacturing the same.

### BACKGROUND OF THE INVENTION

Complementary metal oxide semiconductor (CMOS) integration requires two gate materials, one having a work function near the valence band edge of the semiconductor material in the channel and the other having a work function near the conduction band edge of the same semiconductor material. In CMOS devices having a silicon channel, a conductive material having a work function of about 4.0 eV is necessary for n-type metal oxide semiconductor field effect transistors (NMOSFETs) and another conductive material having a work function of about 5.0 eV is necessary for p-type metal oxide semiconductor field effect transistors (PMOSFETs).

In conventional CMOS devices employing polysilicon gate materials, a heavily p-doped polysilicon gate and a heavily n-doped polysilicon gate are employed to address the needs. Typically, the heavily p-doped polysilicon gate is employed in p-type field effect transistors that provide optimal performance when the work function of the gate electrode is near the valence band edge of the semiconductor material in the channel of the transistor. Likewise, the heavily n-doped polysilicon gate is employed in n-type field effect transistors that provide optimal performance when the work function of the gate electrode is near the conduction band edge of the semiconductor material in the channel of the transistor.

In a high performance CMOS circuit, use of metal gates, i.e., gate electrode structures comprising a metallic material, provides reduction in the resistance of the gate electrode, and consequently reduction in the RC delay and enhanced performance. Unlike polysilicon, however, the work functions of metallic materials do not change in any significant way with dopant concentration. Thus, a pair of suitable metallic materials satisfying the work function requirements is needed to enable a CMOS circuit that contains dual metal gate structures, i.e., a first metal having a work function near the valence band edge of the semiconductor material in the channel and a second metal having a work function near the conduction band edge of the semiconductor material. Further, metal gate structures typically require use of a high-k gate dielectric material to reduce gate leakage current.

Integrating two metal gate materials into a CMOS structure presents challenges in terms of processing complexity that is typically required to form two different types of gate electrodes. Replacement gate integration schemes known in the prior art typically require formation of gate dielectrics after a source/drain activation anneal. Two different metal gate materials are typically formed with accompanying lithographic patterning steps and planarization steps. Many prior art replacement gate integration schemes require two separate steps for formation of gate dielectrics. Thus, while replacement gate integration schemes known in the prior art increases choice of materials for a metal gate electrode, increases in the processing complexity and cost is substantial over typical conventional CMOS process flows.

In view of the above, there exists a need for a semiconductor structure having dual metal gate structures in which two metallic gate electrodes having different work functions are provided, and methods of manufacturing the same.

Further, there exists a need for a semiconductor structure having such dual metal gate structures and including high-k gate dielectrics, and methods of manufacturing the same with minimal processing complexity and cost.

### SUMMARY OF THE INVENTION

The present invention addresses the needs described above by providing a CMOS structure containing a first gate electrode comprising a stack of a first metal portion and a second metal portion located directly on a first gate dielectric and a second gate electrode comprising a third metal portion having the same composition as the second metal portion and located directly on a second gate dielectric, and methods of manufacturing the same.

In the present invention, a stack of a gate dielectric layer, a first metal layer containing a first metal, a disposable material layer, and a dielectric cap layer is lithographically patterned to form two dummy gate structures on a semiconductor substrate. Source and drain regions and metal semiconductor alloy regions are formed thereafter. A dielectric material layer is deposited and planarized so that top surfaces of the two remaining dummy gate structures are substantially coplanar. A disposable material portion and a metal portion are removed from one dummy gate structure, while the other dummy gate structure is protected. Subsequently, another disposable material portion is removed from the other dummy gate structure. A second metal layer comprising a second metal is deposited and planarized to form two gate electrodes. One gate electrode has a gate dielectric abutting the first metal, while the other electrode has a gate electrode abutting the second metal. Both electrodes have the same height since the two top surfaces of the gate electrodes are formed by the same planarization process.

According to an aspect of the present invention, a semiconductor structure is provided, which comprises a first gate stack and a second gate stack located on a semiconductor substrate, wherein the first gate stack comprises a first gate dielectric vertically abutting the semiconductor substrate, a first metal portion vertically abutting the first gate dielectric and comprising a first metallic material, and a second metal portion vertically abutting the first metal portion and comprising a second metallic material which is different from the first metallic material, and wherein the second gate stack comprises a second gate dielectric vertically abutting the semiconductor substrate and a third metal portion vertically abutting the second gate dielectric and comprising the second metallic material.

In one embodiment, the first metal portion has a first thickness, the second metal portion has a second thickness, and the third metal portion has a third thickness, wherein the sum of the first thickness and the second thickness is substantially equal to the third thickness.

In another embodiment, a top surface of the second metal portion and a top surface of the third metal portion are substantially coplanar.

In even another embodiment, the first gate dielectric and the second gate dielectric have a same composition.

In yet another embodiment, the first gate dielectric and the second gate dielectric comprise a material comprises one of HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, an alloy thereof, and non-stoichiometric variants thereof. Each value of x is independently from about 0.5 to about 3 and each value of y is independently from 0 to about 2.

In still another embodiment, the first metallic material has a work function between a valence band edge of a semiconductor material directly underneath the first gate dielectric and a mid-band-gap energy level of the semiconductor material.

In still yet another embodiment, the semiconductor material is silicon, and wherein the first metallic material comprises one of Ru, Pd, Pt, Co, Ni, TaₓAl_{y}N, WₓC_{y}N, a conductive metal oxide, and a combination thereof, wherein each value of x is independently from 0 to about 1 and each value of y is independently from 0 to about 1.

In a further embodiment, the second metallic material has a work function between a conduction band edge of a semiconductor material directly underneath the second gate dielectric and a mid-band-gap energy level of the semiconductor material.

In an even further embodiment, the semiconductor material is silicon, and wherein the second metallic material comprises one of Zr, W, Ta, Hf, Ti, Al, a metal carbide, a transition metal aluminide, and a combination thereof.

In a yet further embodiment, the semiconductor structure further comprises:

a first source region and a first drain region, each having a doping of a first conductivity type, abutting the first gate dielectric, located in the semiconductor substrate, and separated from each other; and

a second source region and a second drain region, each having a doping of a second conductivity type, abutting the second gate dielectric, located in the semiconductor substrate, and separated from each other, and separated from the first source region and the first drain region, wherein the second conductivity type is the opposite type of the first conductivity type.

In a still further embodiment, the semiconductor structure further comprises:

a first source side metal semiconductor alloy vertically abutting the first source region;

a first drain side metal semiconductor alloy vertically abutting the first drain region;

a second source side metal semiconductor alloy vertically abutting the second source region; and

a second drain side metal semiconductor alloy vertically abutting the second drain region.

In a still yet further embodiment, the semiconductor structure further comprises a dielectric material layer abutting the semiconductor substrate and having a top surface which is substantially coplanar with a top surface of the second metal portion and a top surface of the third metal portion.

According to another aspect of the present invention, a method of forming a semiconductor structure is provided, which comprises:

forming a first dummy gate structure and a second dummy gate structure on a semiconductor substrate, wherein the first dummy gate structure includes a stack of a first gate dielectric, a first metal portion comprising a first metallic material, and a first disposable material portion from bottom to top in that order and the second dummy gate structure includes a stack of a second gate dielectric, a second metal portion comprising the first metallic material, and a second disposable material portion from bottom to top in that order;

removing the second disposable material portion and the second metal portion, while preserving, i.e., protecting, an entirety of the second gate dielectric and the first disposable material portion;

removing the first disposable material portion, while preserving, i.e., protecting, an entirety of the first metal portion; and

forming a third metal portion directly on the second gate dielectric and a fourth metal portion directly on the first metal portion, wherein the third metal portion and the fourth metal portion comprise a second metallic material.

In one embodiment, the first metallic material and the second metallic material are different from each other.

In another embodiment, the method further comprises:

forming a gate dielectric layer directly on the semiconductor substrate;

forming a first metal layer directly on the gate dielectric layer; and

forming a disposable material layer directly on the first metal layer, wherein the first and second gate dielectrics are formed by patterning of the gate dielectric layer, wherein the first and second metal portions are formed by patterning of the first metal layer, and wherein the first and second disposable material portions are formed by patterning of the disposable material layer.

In even another embodiment, the method further comprises:

depositing a dielectric material layer over the first dummy gate structure, the second dummy gate structure, and the semiconductor substrate; and

planarizing the dielectric material layer, wherein a top surface of the first dummy gate structure and a top surface of the second dummy gate structure are substantially coplanar with a top surface of the dielectric material layer after the planarizing.

In yet another embodiment, the first dummy gate structure includes a first dielectric cap and the second dummy gate structure includes a second dielectric cap, and the method further comprises removing the first and second dielectric cap during the planarizing.

In still another embodiment, the method further comprises:

forming a first source region and a first drain region prior to removal of the first disposable material portion and the first metal portion, wherein each of the first source region and the first drain region has a doping of a first conductivity type, abuts the first gate dielectric, is located in the semiconductor substrate, and is separated from each other; and

forming a second source region and a second drain region prior to the removal of the first disposable material portion and the first metal portion, wherein each of the second source region and the second drain region has a doping of a second conductivity type, abuts the second gate dielectric, is located in the semiconductor substrate, and is separated from each other, and wherein the second conductivity type is the opposite type of the first conductivity type.

In still yet another embodiment, the method further comprises forming a first source side metal semiconductor alloy, a first drain side metal semiconductor alloy, a second source side metal semiconductor alloy, and a second drain side metal semiconductor alloy prior to the removal of the first disposable material portion and the first metal portion, wherein the first source side metal semiconductor alloy is formed directly on the first source region, the first drain side metal semiconductor alloy is formed directly on the first drain region, the second source side metal semiconductor alloy is formed directly on the second source region, and the second drain side metal semiconductor alloy is formed directly on the second drain region.

In a further embodiment, the method further comprises:

depositing a second metal layer on the second gate dielectric and the first metal portion; and

removing portions of the second metal layer above the dielectric material layer, wherein the third metal portion and the fourth metal portions are remaining portions of the second metal layer after the removing.

### BRIEF DESCRIPTION OF THE DRAWINGS

FIGS. 1-10 are sequential vertical cross-sectional views of an exemplary semiconductor structure according to the present invention at various stages of a manufacturing process.

### DETAILED DESCRIPTION OF THE INVENTION

As stated above, the present invention relates to complementary metal-oxide-semiconductor (CMOS) devices having dual metal gate structures, and methods of manufacturing the same, which are now described in detail with accompanying figures. It is noted that like and corresponding elements are referred to by like reference numerals.

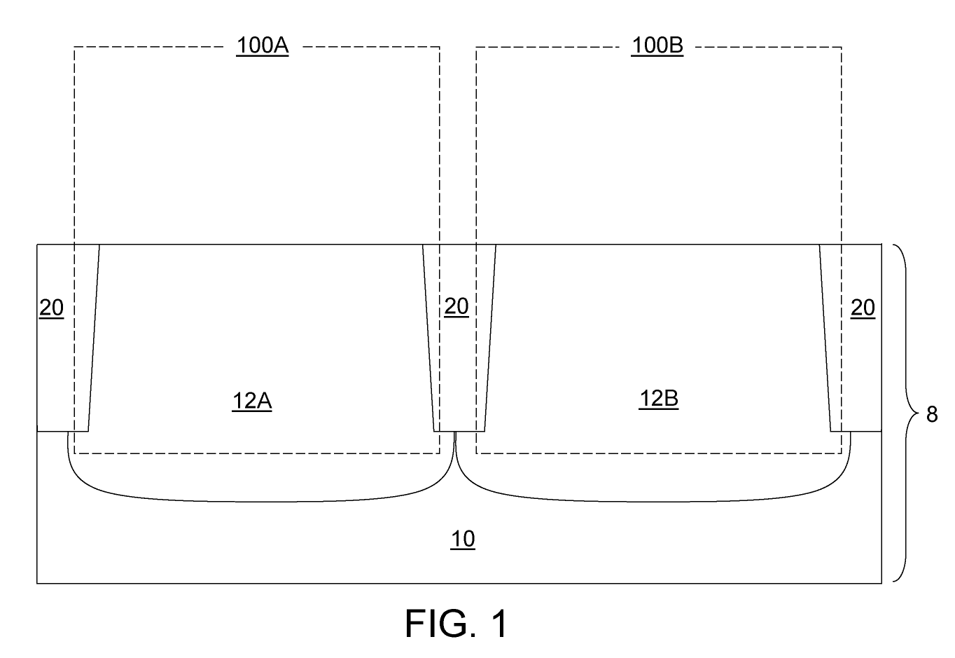

Referring to FIG. 1, an exemplary semiconductor structure according to the present invention comprises a semiconductor substrate 8 containing a substrate semiconductor layer 10, a first conductivity type well 12A, a second conductivity type well 12B, and a shallow trench isolation structure 20. The substrate semiconductor layer 10, the first conductivity type well 12A, and the second conductivity type well 12B comprise a semiconductor material, which may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material comprises silicon. Preferably, the first conductivity type well 12A, the second conductivity type well 12B, and the substrate semiconductor layer 10 are single crystalline. The semiconductor substrate 8 may be a bulk substrate, a semiconductor-on-insulator (SOI) substrate, or a hybrid substrate. The semiconductor substrate 8 may have a built-in stress in the first conductivity type well 12A, the second conductivity type well 12B, and/or the substrate semiconductor layer 10. While the present invention is described with a bulk substrate, implementation of the present invention on an SOI substrate or on a hybrid substrate is explicitly contemplated herein.

The shallow trench isolation structure 20 comprises a dielectric material such as silicon oxide or silicon nitride, and is formed by methods well known in the art. The exemplary semiconductor structure comprises a first device region 100A, in which a first field effect transistor is to be subsequently formed, and a second device region 100B, in which a second field effect transistor is to be subsequently formed. The first device region 100A includes a portion of the first conductivity type well 12A, and the second device region 100B includes a portion of the second conductivity type well 12B. The first conductivity type well 12A has a doping of a first conductivity type, which may be p-type or n-type, and the second conductivity type well 12B has a doping of a second conductivity type, which is the opposite of the first conductivity type. For example, if the first conductivity type is p-type, the second conductivity type is n-type, and vice versa. The semiconductor layer 10 may have a doping of the first conductivity type or a doping of the second conductivity type. Alternately, the semiconductor layer 10 may be substantially undoped, i.e., intrinsic.

The dopant concentration in the first conductivity type well 12A and the second conductivity type well 12B depends on desired device characteristics of the transistors to be formed in the first and second device regions (100A, 100B), and may be from about 1.0×10¹⁵/cm³ to about 1.0×10¹⁹/cm³, and typically from about 1.0×10¹⁶/cm³ to about 3.0×10¹⁸/cm³, although lesser and greater dopant concentrations are contemplated herein also. The dopant concentration of the semiconductor layer 10 may be substantially the same as, or lower than, the dopant concentration of one of the first conductivity type well 12A and second conductivity type well 12B that has a doping of the same conductivity type. The dopant concentration of the semiconductor layer 10 may be from about 1.0×10¹⁴/cm³ to about 1.0×10¹⁹/cm³, and typically from about 1.0×10¹⁵/cm³ to about 3.0×10¹⁸/cm³, although lesser and greater dopant concentrations are contemplated herein also.

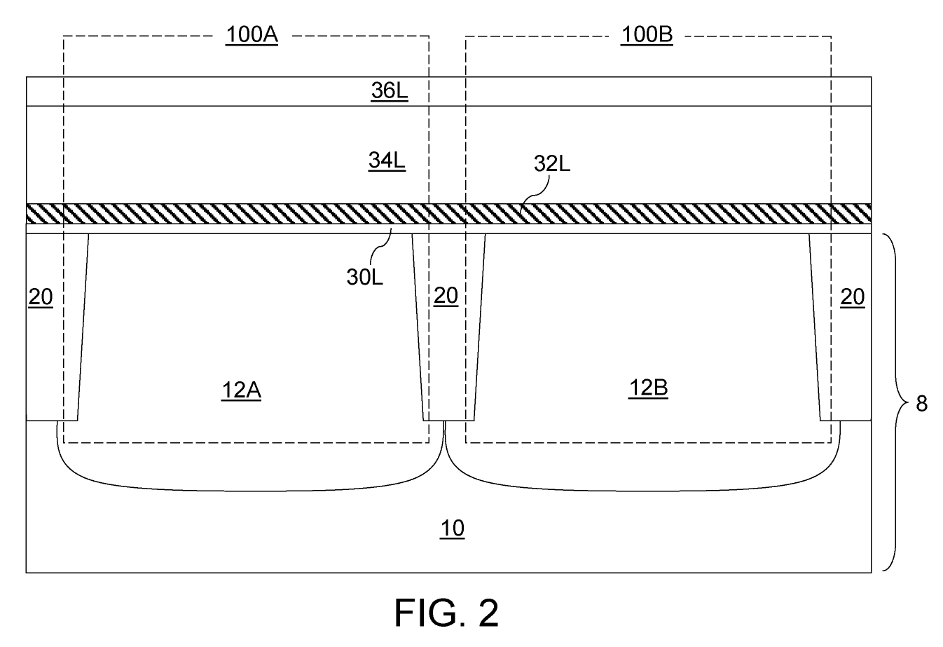

Referring to FIG. 2, a gate dielectric layer 30L is formed on a top surface of the semiconductor substrate. Preferably, the gate dielectric layer 30L comprises a high dielectric constant (high-k) material comprising a dielectric metal oxide and having a dielectric constant that is greater than the dielectric constant of silicon nitride of 7.5. The gate dielectric layer 30L may be formed by methods well known in the art including, for example, chemical vapor deposition (CVD), atomic layer deposition (ALD), molecular beam deposition (MBD), pulsed laser deposition (PLD), liquid source misted chemical deposition (LSMCD), etc.

The dielectric metal oxide comprises a metal and oxygen, and optionally nitrogen and/or silicon. Exemplary high-k dielectric materials include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from about 0.5 to about 3 and each value of y is independently from 0 to about 2. The thickness of the gate dielectric layer 30L may be from about 1 nm to about 10 nm, and preferably from about 1.5 nm to about 3 nm. The gate dielectric layer 30L may have an effective oxide thickness (EOT) on the order of, or less than, 1 nm.

The gate dielectric layer 30L, when it comprises a high-k dielectric material, may optionally further comprise an interfacial layer (not shown) between the portion of the high-k dielectric material and the semiconductor substrate 8. The interfacial layer, which preferably comprises silicon oxide or silicon oxynitride, helps minimize mobility degradation due to high-k dielectric material.

A first metal layer 32L is formed on the gate dielectric layer 30L, for example, by chemical vapor deposition (CVD), physical vapor deposition (PVD), atomic layer deposition (ALD), etc. The first metal layer 32L comprises a first metallic material which may comprise an elemental metal, a metal alloy, a conductive metal oxide, and/or a conductive metal nitride.

In one embodiment, the first conductivity type well 12A has a n-type doping, the second conductivity type well 12B has an p-type doping, and the first metal layer 32L has a work function between a valence band edge of the semiconductor material of the first conductivity type well 12A and a mid-band-gap energy level of the semiconductor material of the first conductivity type well 12A. For example, if the semiconductor material is silicon, the first metallic material may comprise one of Ru, Pd, Pt, Co, Ni, TaₓAl_{y}N, WₓC_{y}N, a conductive metal oxide, and a combination thereof. Each value of x is independently from 0 to about 1 and each value of y is independently from 0 to about 1.

In an alternate embodiment, the first conductivity type well 12A has an p-type doping, the second conductivity type well 12B has a n-type doping, and the first metal layer 32L has a work function between a conduction band edge of the semiconductor material of the first conductivity type well 12A and a mid-band-gap energy level of the semiconductor material of the first conductivity type well 12A. For example, if the semiconductor material is silicon, the first metallic material may comprise one of Zr, W, Ta, Hf, Ti, Al, a metal carbide, a transition metal aluminide, and a combination thereof. Exemplary transition metal aluminide include Ti₃Al and ZrAl.

The thickness of the first metal layer 32L may be from about 3 nm to about 100 nm, and preferably from about 5 nm to about 30 nm. Preferably, the composition of the first metal layer 32L, and as a consequence, the work function of the first metal layer 20L, is selected to optimize the threshold voltage of a transistor to be subsequently formed in the first device region 100A.

A disposable material layer 34L is formed directly on the first metal layer 32L by chemical vapor deposition (CVD) such as low pressure chemical vapor deposition (LPCVD), rapid thermal chemical vapor deposition (RTCVD), plasma enhanced chemical vapor deposition (PECVD), etc. The disposable material layer 34L may comprise a semiconductor material, a metallic material, or a dielectric material. The disposable material layer 34L comprises a material that may be removed selective to the first metallic material of the first metal layer 32L and the material of a dielectric material layer to be subsequently formed over the semiconductor substrate 8. In case the disposable material layer 34L comprises a semiconductor material, the disposable material layer may be amorphous or polycrystalline. Non-limiting exemplary materials for the disposable material layer 34L include silicon, germanium, a silicon-germanium alloy, a silicon carbon alloy, a silicon-germanium-carbon alloy, gallium arsenide, indium arsenide, indium phosphide, III-V compound semiconductor materials, II-VI compound semiconductor materials, organic semiconductor materials, and other compound semiconductor materials. In case the disposable material layer 34L comprises a dielectric material, the disposable material layer 34L may comprise a porous or non-porous dielectric material that may be easily etched selective to the first metallic material. In case the disposable material layer 34L comprises a metal, the disposable material layer 34L comprises a metal that may be selectively etched relative to the first metallic material. The thickness of the disposable material layer 34L may be from about 10 nm to about 150 nm, and typically from about 50 nm to about 120 nm, although lesser and greater thicknesses are also explicitly contemplated herein.

Optionally, a dielectric cap layer 36L is formed directly on the disposable material layer 34L. The dielectric cap layer 36L comprises a dielectric material such as a dielectric oxide or a dielectric nitride. Exemplary dielectric materials include silicon oxide and silicon nitride. Preferably, the dielectric cap layer 36L, when present, comprises a dielectric material that may be employed as a stopping layer in a subsequent planarization processing step as a chemical mechanical polish stopping layer and/or an etch stop layer if an etch is employed during the planarization processing step. For example, the dielectric cap layer 36L may comprise silicon nitride. The thickness of the dielectric cap layer 36L may be in the range from about 3 nm to about 200 nm, and typically from about 10 nm to about 50 nm. The dielectric cap layer 36L may be formed by plasma enhanced chemical vapor deposition (PECVD), high density plasma chemical vapor deposition (HDPCVD), low pressure chemical vapor deposition (LPCVD) or rapid thermal chemical vapor deposition (RTCVD), or any other suitable method.

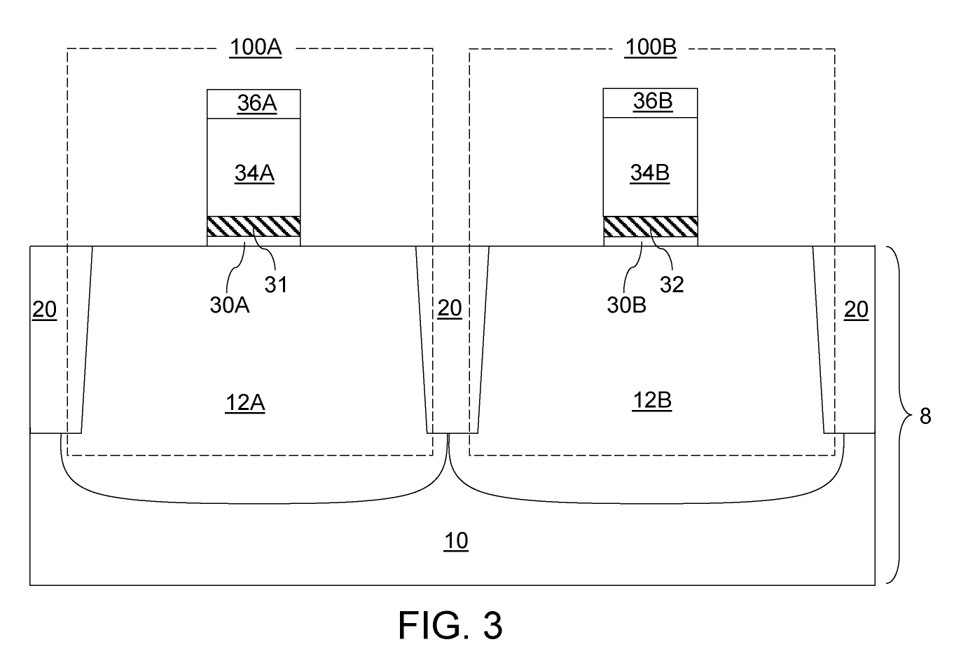

Referring to FIG. 3, the stack of the gate dielectric layer 30L, the first metal layer 32L, the disposable material layer 34L, and the dielectric cap layer 36L is patterned to form a first dummy gate stack in the first device region 100A and a second dummy gate stack in the second device region 100B. Specifically, a masking layer (not shown) is applied over the dielectric cap layer 36L and patterned by methods known in the art. The pattern in the masking layer is subsequently transferred by an anisotropic etch into the stack of the gate dielectric layer 30L, the first metal layer 32L, the disposable material layer 34L, and the dielectric cap layer 36L, thus patterning each layer in the pattern of the masking layer. The masking layer may comprise a photoresist layer, or a photoresist layer on top of a hardmask layer. Preferably, the section of the anisotropic etch that patterns the gate dielectric layer 30L is selective to the semiconductor material of the first conductivity type well 12A and the second conductivity type well 12B. The masking layer is removed after patterning the gate stacks.

The first dummy gate stack comprises a first gate dielectric 30A, a first metal portion 31, a first disposable material portion 34A, and a first dielectric cap 36A from bottom to top. The second dummy gate stack comprises a second gate dielectric 30B, a second metal portion 32, a second disposable material portion 34B, and a second dielectric cap 36B from bottom to top. The first dummy stack (30A, 31, 34A, 36A) is patterned in the form of a gate line for a first transistor to be formed in the first device region 100A. The second dummy stack (30B, 32, 34B, 36B) is patterned in the form of a gate line for a second transistor to be formed in the second device region 200A. The first dummy gate stack (30A, 31, 34A, 36A) and the second dummy gate stack (30B, 32, 34B, 36B) comprise the same film stack at this stage. Therefore, the first dummy gate stack (30A, 31, 34A, 36A) and the second dummy gate stack (30B, 32, 34B, 36B) may be simultaneously patterned by a common patterning processing step.

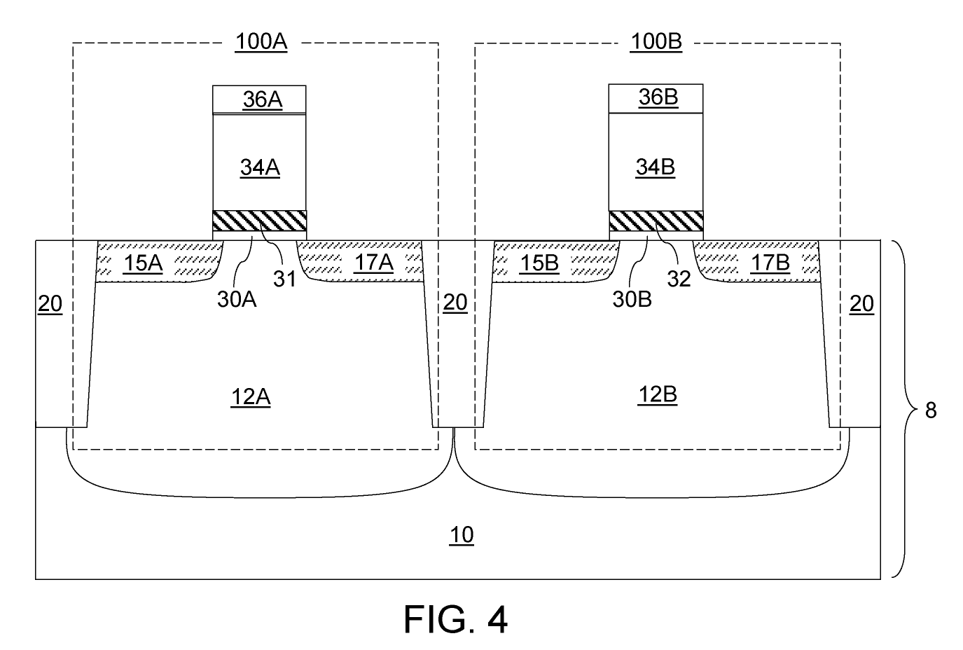

Referring to FIG. 4, source and drain extension regions are formed by masked ion implantations. Typically, a first block mask (not shown) is applied over first and second device regions (100A, 100B) and lithographically patterned to cover one of the first and second device regions (1000A or 100B), while exposing the other of the first and second device regions (100B or 100A). For example, the first device region 100A may be exposed and the second device region 100B may be covered by the first block mask. Dopants of the opposite conductivity type than the conductivity type of the exposed well, i.e., the first conductivity type well 12A or the second conductivity type well 12B, are implanted into the exposed regions to form a set of a source extension region and a drain extension region. For example, if the first device region 100A is exposed and the second device region 100B is covered by the first block mask, dopants of the second conductivity type are implanted into the first conductivity type well 12A to form a first source extension region 15A and a first drain extension region 17A having a doping of the second conductivity type.

The first block mask is removed and a second block mask (not shown) is applied and patterned such that the device region (100A or 100B) previously blocked by the first block mask is exposed, while the device region (100B or 100A) previously exposed is blocked by the second block mask. Dopants of the opposite conductivity type than the conductivity type of the exposed well are implanted into the exposed regions to form another set of a source extension region and a drain extension region. For example, if the second device region 100B is exposed and the first device region 100A is covered by the second block mask, dopants of the first conductivity type are implanted into the second conductivity type well 12B to form a second source extension region 15B and a first drain extension region 17B having a doping of the first conductivity type. Optionally, halo implantations that provide the same type of dopants into the first and/or second conductivity type wells (12A, 12B) may be performed employing the first and/or second block masks. The order of formation between the first source and drain extension regions (15A, 17A) and the second source and drain extension regions (15B, 17B) may, or may not, be reversed.

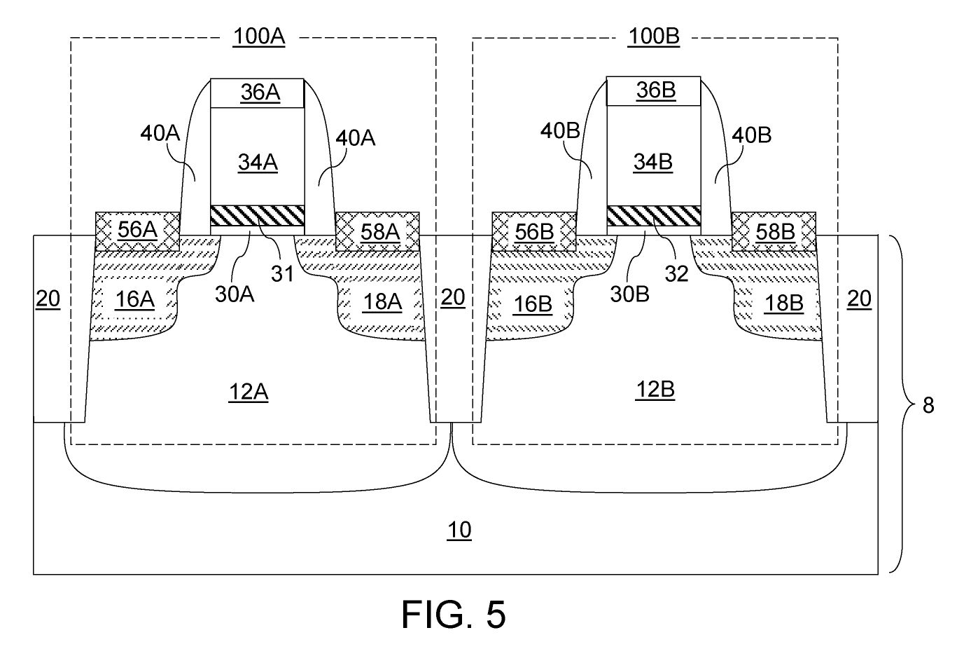

Referring to FIG. 5, a first gate spacer 40A and a second gate spacer 40B are formed on the first and second dummy gate stacks. Specifically, the first gate spacer 40A is formed on the sidewalls of the first gate dielectric 30A, the first metal portion 31, and the first disposable material portion 34A. Similarly, the second gate spacer 40B is formed on the sidewalls of the second gate dielectric 30B, the second metal portion 32, and the second disposable material portion 34B. The first and second gate spacers (40A, 40B) are formed by a substantially conformal deposition of a dielectric material such as silicon oxide, silicon nitride, silicon oxynitride, or a combination thereof, followed by an anisotropic etch that removes horizontal portions of the dielectric material. The remaining vertical portions of the dielectric material constitute the first gate spacer 40A and the second gate spacer 40B. Preferably, the first gate spacer 40A abuts the sidewalls of the first dielectric cap 36A and the second gate spacer 40B abuts the sidewalls of the second gate dielectric cap 36B, although embodiments in which the first and second gate spacers do not abut the sidewalls of the first and second dielectric caps (36A, 36B) are also contemplated herein.

Typically, a third block mask (not shown) is applied over first and second device regions (100A, 100B) and lithographically patterned to cover one of the first and second device regions (1000A or 100B), while exposing the other of the first and second device regions (100B or 100A). For example, the first device region 100A may be exposed and the second device region 100B may be covered by the third block mask. Dopants of the same conductivity type as the conductivity type of the exposed source and drain extension regions, i.e., the first source and drain extension regions (15A, 17A) or the second source and drain extension regions (15B, 17B), are implanted into the exposed regions to increase the volume of the doped regions including the exposed source and drain extension regions. The exposed doped regions, now having an increased volume due to the additional ion implantation, constitute a set of a source region and a drain region. For example, if the first device region 100A is exposed and the second device region 100B is covered by the third block mask, dopants of the second conductivity type are implanted into the portions of the first conductivity type well 12A directly underneath the first source extension region 15A and the second drain extension region 17A to form a first source region 16A and a first drain region 18A having a doping of the second conductivity type and including the volume of the first source extension region 15A and the second drain extension region 17A, respectively.

The third block mask is removed and a fourth block mask (not shown) is applied and patterned such that the device region (100A or 100B) previously blocked by the third block mask is exposed, while the device region (100B or 100A) previously exposed is blocked by the fourth block mask. Dopants of the same conductivity type as the conductivity type of the exposed source and drain extension regions are implanted into the exposed regions to increase the volume of the doped regions including the exposed source and drain extension regions. The exposed doped regions, now having an increased volume due to the additional ion implantation, constitute another set of a source region and a drain region. For example, if the second device region 100B is exposed and the first device region 100A is covered by the fourth block mask, dopants of the first conductivity type are implanted into the portions of the second conductivity type well 12B directly underneath the second source extension region 15B and the second drain extension region 17B to form a second source region 16B and a second drain region 18B having a doping of the second conductivity type and including the volume of the second source extension region 15B and the second drain extension region 17B, respectively. The order of formation between the first source and drain regions (16A, 18A) and the second source and drain regions (16B, 18B) may, or may not, be reversed.

The dopant concentration of the first source and drain regions (16A, 18A) and the second source and drain regions (16B, 18B) may be from about 1.0×10¹⁹/cm³ to about 1.0×10²¹/cm³, and typically from about 1.0×10²⁰/cm³ to about 5.0×10²⁰/cm³, although lesser and greater dopant concentrations are contemplated herein also. Replacing the semiconductor materials within the first source and drain regions (16A, 18A) and the second source and drain regions (16B, 18B) prior to or after implantation of dopants with at least another semiconductor material, such as silicon carbon alloy or a silicon germanium alloy is explicitly contemplated herein also.

A metal layer (not shown) is formed over the first source and drain regions (16A, 18A) and the second source and drain regions (16B, 18B) and reacted with the first source and drain regions (16A, 18A) and the second source and drain regions (16B, 18B) to form metal semiconductor alloy regions. The metal layer comprises a metal that reacts with the semiconductor material in the first source and drain regions (16A, 18A) and the second source and drain regions (16B, 18B). Non-limiting exemplary materials for the metal layer include nickel, platinum, palladium, cobalt or a combination thereof. The formation of the metal layer may be effected by physical vapor deposition (PVD), chemical vapor deposition (CVD), or atomic layer deposition (ALD). The metal layer may be deposited in a conformal or non-conformal manner. Preferably, the metal deposition is substantially conformal.

The various semiconductor portions in direct contact with the metal layer are metallized by reacting with the metal in the metal layer during a metallization anneal. The metallization is effected by an anneal at a temperature from about 350° C. to about 550° C., which is typically performed in an inert gas atmosphere, e.g., He, Ar, N₂, or forming gas. Preferably, the anneal is performed at a temperature from about 400° C. to about 500° C. A continuous heating at a constant temperature or various ramping in temperature may be employed. The metallization may further be effected by an additional anneal at a temperature from about 400° C. to about 750° C., and preferably from about 500° C. to about 700° C. After the metallization process, unreacted portions of the metal layer 70, which are present over dielectric surfaces such as the first and gate spacers (52, 52′) and the shallow trench isolation structure 32, are removed selective to various metal semiconductor alloy portions by an etch, which may be a wet etch. A typical etchant for such a wet etch employs aqua regia.

The metallization forms a first source side metal semiconductor alloy 56A directly on the first source region 16A, a first drain side metal semiconductor alloy 58A directly on the first drain side 18A, a second source side metal semiconductor alloy 56B directly on the second source side 16B, and a second drain side metal semiconductor ally 58 directly on the second drain region 18B, respectively. In case the semiconductor substrate 8 comprises silicon, the various metal semiconductor alloys (56A, 58A, 56B, 58B) may comprise a metal silicide.

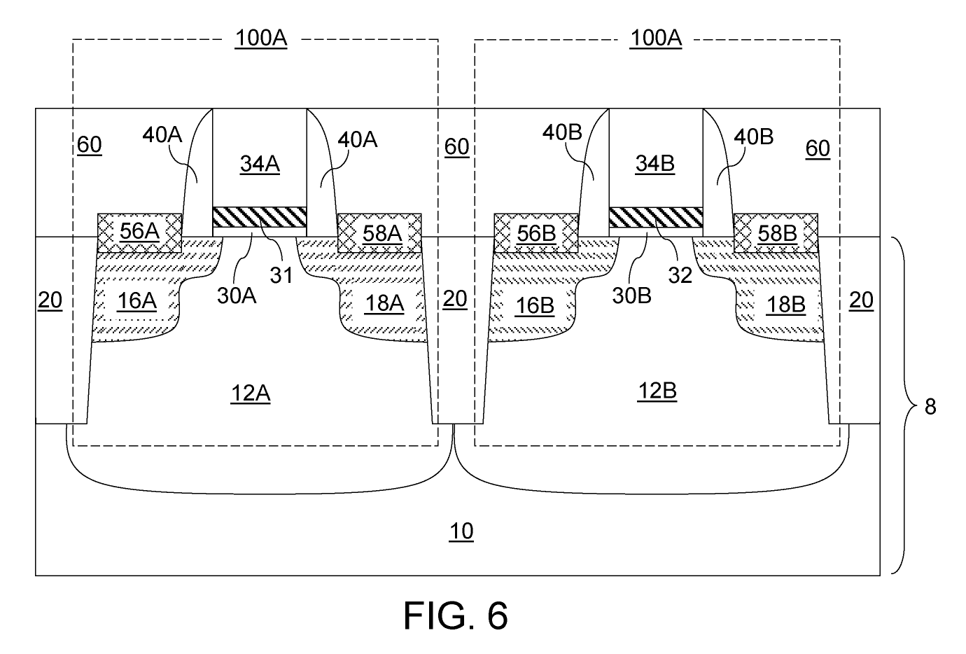

Referring to FIG. 6, a dielectric material layer 60 is deposited over the entirety of the top surfaces of the exemplary semiconductor structure, i.e., over the first dummy gate structure (30A, 31, 34A, 36A), the second dummy gate structure (30B, 32, 34B, 36B), the first and second gate spacers (40A, 40B), the various metal semiconductor alloys (56A, 58A, 56B, 58B), and the shallow trench isolation structure 20. The dielectric material layer 60 comprises a dielectric material such as silicon oxide, silicon nitride, silicon oxynitride, or a combination thereof.

A dielectric material layer 60 may, or may not, include a mobile ion barrier layer (not shown) which typically comprises an impervious dielectric material such as silicon nitride and directly contacts the various metal semiconductor alloys (56A, 58A, 56B, 58B) and the first and second gate spacers (40A, 40B). The dielectric material layer 60 may comprise, for example, a spin-on-glass and/or chemical vapor deposition (CVD) oxide such as undoped silicate glass (USG), borosilicate glass (BSG), phosphosilicate glass (PSG), fluorosilicate glass (FSG), borophosphosilicate glass (BPSG), or a combination thereof. Alternately, the dielectric material layer 60 may comprise a low-k dielectric material having a dielectric constant less than 3.9 (the dielectric constant of silicon oxide), and preferably less than about 2.5. Exemplary low-k dielectric materials include organosilicate glass (OSG) and SiLK™.

The dielectric material layer 60 is subsequently planarized to form a substantially planar top surface. Preferably, the first and second dielectric caps (36A, 36B), when present, are employed as a stopping layer. Upon exposure of the first and second dielectric caps (36A, 36B), the planarization process may non-selectively remove the first and second dielectric caps (36A, 36B) and the dielectric material layer 60, or alternately, employ a reactive ion etch that removes the first and second dielectric caps (36A, 36B) and the dielectric material layer 60 without selectivity, i.e., at substantially the same removal rate. Yet alternately, the first and second dielectric caps (36A, 36B) may be removed by an etch that is selective to the first and second disposable material portions (34A, 34B), followed by additional planarization of the dielectric material layer 60. After the planarization processing step, the top surfaces of the first and second dielectric caps (36A, 36B) are exposed, which are substantially coplanar with each other and with a top surface of the dielectric material layer 60.

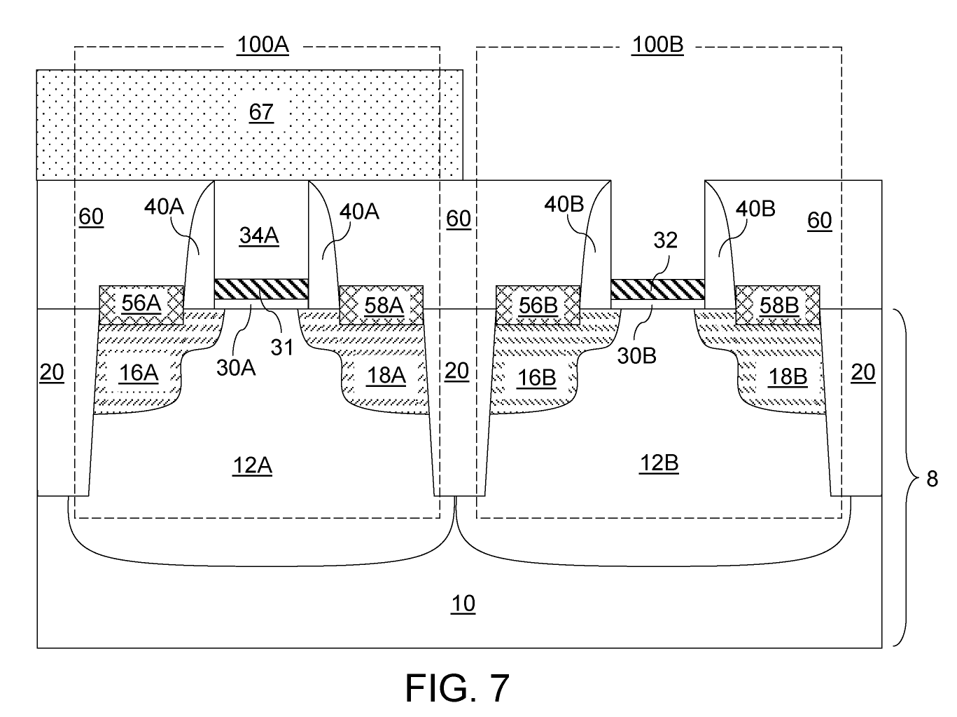

Referring to FIG. 7, a photoresist 67 is applied over the top surfaces of the dielectric material layer 60 and the first and second disposable material portions (34A, 34B), and lithographically patterned to expose the second device region 100B, while covering the first device region 100A. The second disposable material portion 34B is removed by a first etch, which is selective to the dielectric material layer 60. Preferably, the first etch is also selective to the second gate spacer 40B. The first etch may be a dry etch, such as a reactive ion etch (RIE) or a chemical downstream etch (CDE), or a wet etch. For example, the dielectric material layer 60 may comprise silicon oxide, the second gate spacer 40B may comprise silicon oxide, silicon oxynitride, or silicon nitride, and the second disposable material portion 34B may comprise silicon, germanium, a silicon-germanium alloy, or any other material that may be selectively etched relative to silicon oxide and/or silicon nitride. Etch chemistries that remove silicon, germanium, a silicon-germanium alloy selective to silicon oxide and/or silicon nitride are known in the art. The first etch may, or may not, be selective to the first metallic material of the second metal portion 32.

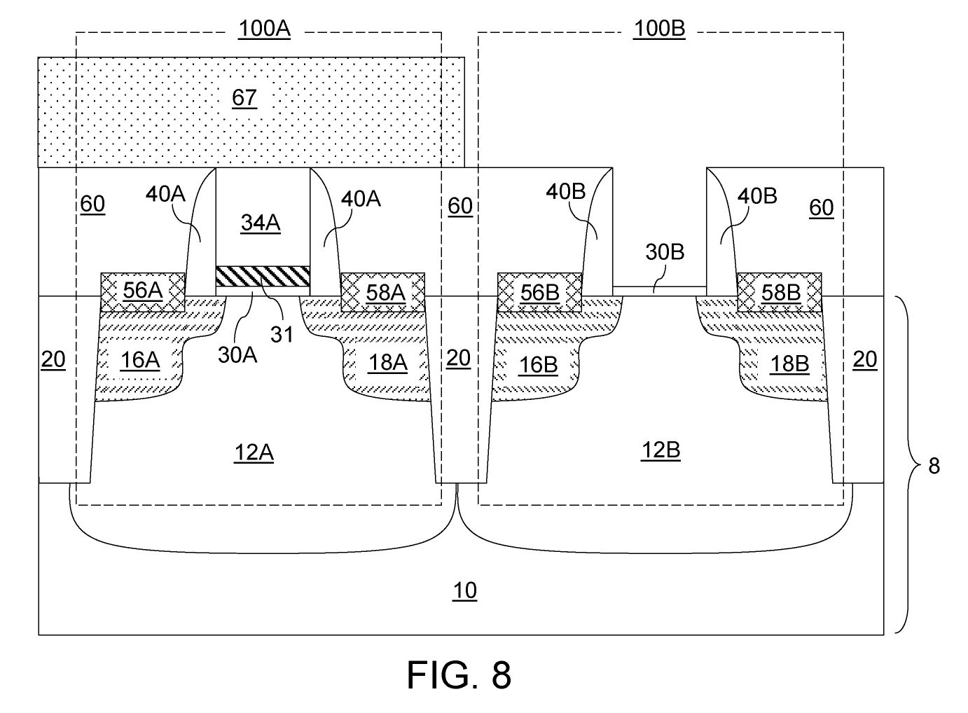

Referring to FIG. 8, with the photoresist 67 in place, the second metal portion 32 is removed selective to the second gate dielectric 30B by a second etch. The second etch may, or may not, be selective to the dielectric material layer 60 and/or the second gate spacer 40B. Preferably, the second etch is selective to the dielectric material layer 60 and the second gate spacer 40B. The second etch may be a dry etch, such as a reactive ion etch (RIE) or a chemical downstream etch (CDE), or a wet etch. Etch chemistries that remove a metallic material selective dielectric materials are also known in the art. The photoresist 67 is removed after removing the second metal portion 32. Alternatively, the photoresist 67 can be removed before removing the second metal portion 32.

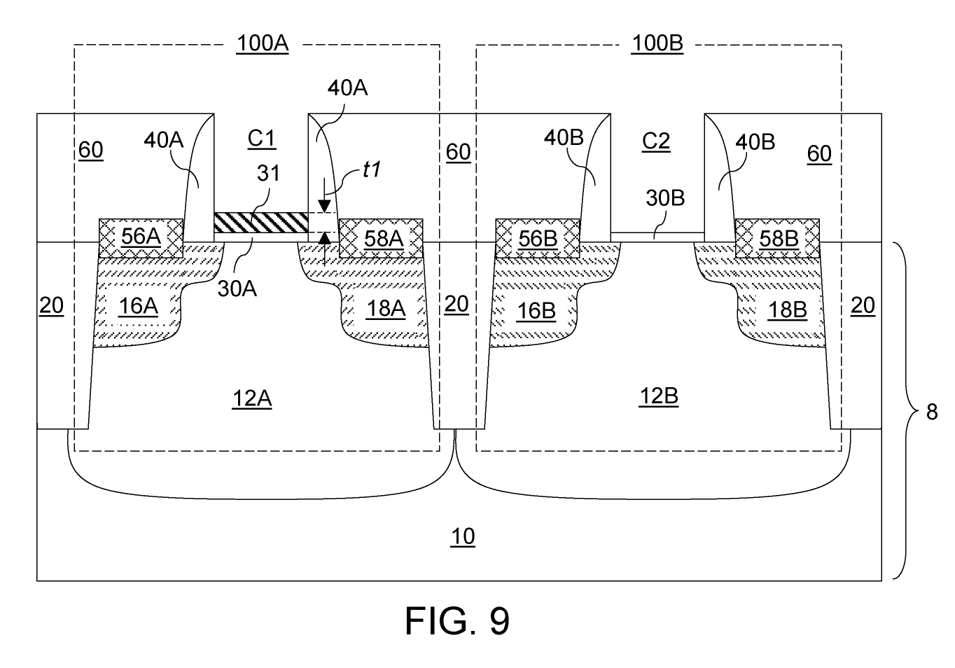

Referring to FIG. 9, the first disposable material portion 34A is removed by a third etch, which is selective to the dielectric material layer 60. Preferably, the third etch is also selective to the first and second gate spacers (40A, 40B). The third etch may be a dry etch, such as a reactive ion etch (RIE) or a chemical downstream etch (CDE), or a wet etch, and may, or may not, employ the same chemistry as the first etch. For example, the dielectric material layer 60 may comprise silicon oxide, the first and second gate spacers (40A, 40B) may comprise silicon oxide, silicon oxynitride, or silicon nitride, and the first disposable material portion 34A may comprise silicon, germanium, a silicon-germanium alloy, or any other material that may be selectively etched relative to silicon oxide and/or silicon nitride. Preferably, the third etch is selective to the first metallic material of the first metal portion 31.

A first cavity C1 surrounded by the first gate spacer 40A is formed above the first metal portion 31. Also, a second cavity C2 surrounded by the second gate spacer 40B is formed above the second gate dielectric 30B. The depth of the second cavity C2, as measured from the top surface of the dielectric material layer 60, is greater than the depth of the first cavity C₁, as measured from the top surface of the dielectric material layer 60, by the thickness of the first metal portion 31, which is herein referred to as a first thickness t1.

In one embodiment of the present invention, another photoresist (not shown) is applied over the exemplary semiconductor structure after the removal of the second metal portion 32 and prior to removal of the first disposable material portion 34A, and lithographically patterned to cover the second device region 100B, while exposing the first device region 100 so that the second gate dielectric 30B may be protected during the removal of the first disposable material portion 34A. The photoresist is subsequently removed.

In another embodiment of the present invention, the order of removal is reversed between the first disposable material portion 34A and the set of the second disposable material portion 34B and the second metal portion 32.

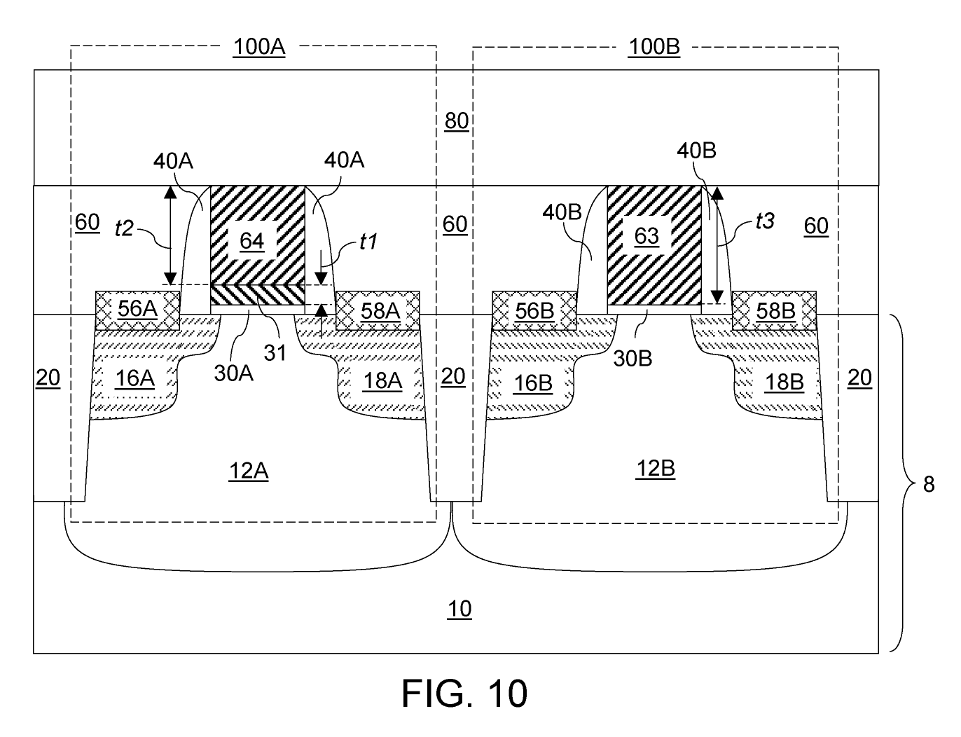

Referring to FIG. 10, a second metal layer comprising a second metallic material is deposited within the first cavity C1 and the second cavity C2, and is planarized employing the top surface of the dielectric material layer 60 as a stopping layer during the planarization processing step. As a result, a third metal portion 63 comprising the second metallic material is formed directly above the second gate dielectric 30B, i.e., the third metal portion 63 fills the second cavity C2. A fourth metal portion 64 also comprising the second metallic material is formed directly above the first metal portion 31, i.e., the fourth metal portion 64 fills the first cavity C1. The top surfaces of the third metal portion 63 and the fourth metal portion 64 are substantially coplanar with the top surface of the dielectric material layer 60.

The fourth metal portion has a second thickness t2, and the third metal portion has a third thickness t3. Since the thickness of the first gate dielectric 30A and the thickness of the second gate dielectric 30B are the same and the top surface of the third metal portion 63 and the top surface of the fourth metal portion 64 are located at substantially the same height, the sum of the first thickness t1 and the second thickness t2 is substantially the same as the third thickness t3.

The second metal layer may be formed, for example, by chemical vapor deposition (CVD), physical vapor deposition (PVD), atomic layer deposition (ALD), etc. The second metallic material may be an elemental metal, a metal alloy, a conductive metal oxide, or a conductive metal nitride. The thickness of the second metal layer is thick enough to fill the first cavity C1 and the second cavity without any void in the third metal portion 63 or in the fourth metal portion 64. Preferably, the composition of the second metal layer, and as a consequence, the work function of the third metal portion 63, is selected to optimize the threshold voltage of a second transistor in the second device region 100B. Since the first metal portion 31 is located directly above the first gate dielectric 30A, the threshold voltage of a first transistor located in the first device region 100A and including the first gate dielectric 30A is determined by the work function of the first metal portion 31, and not by the work function of the fourth metal portion 64.

In one embodiment, the first conductivity type well 12A has an n-type doping, the second conductivity type well 12B has a p-type doping, and the first metal layer 31 has a work function between a valence band edge of the semiconductor material of the first conductivity type well 12A and a mid-band-gap energy level of the semiconductor material of the first conductivity type well 12A as described above. In this case, the second metallic material in the second metal layer, and consequently, in the third metal portion 63 and the fourth metal portion 64, has a work function between a conduction band edge of the semiconductor material of the second conductivity type well 12B and a mid-band-gap energy level of the semiconductor material of the second conductivity type well 12B. For example, if the semiconductor material of the second conductivity type well 12B is silicon, the second metallic material may comprise one of Zr, W, Ta, Hf, Ti, Al, a metal carbide, a transition metal aluminide, and a combination thereof. In this case, if the semiconductor material of the first conductivity type well 12A is silicon also, the first metal portion 31 may comprise one of Ru, Pd, Pt, Co, Ni, TaₓAl_{y}N, WₓC_{y}N, a conductive metal oxide, and a combination thereof. Each value of x is independently from 0 to about 1 and each value of y is independently from 0 to about 1.

In an alternate embodiment, the first conductivity type well 12A has a p-type doping, the second conductivity type well 12B has a n-type doping, and the first metal layer 31 has a work function between a conduction band edge of the semiconductor material of the first conductivity type well 12A and a mid-band-gap energy level of the semiconductor material of the first conductivity type well 12A as described above. In this case, the second metallic material in the second metal layer, and consequently, in the third metal portion 63 and the fourth metal portion 64, has a work function between a valence band edge of the semiconductor material of the second conductivity type well 12B and a mid-band-gap energy level of the semiconductor material of the second conductivity type well 12B. For example, if the semiconductor material of the second conductivity type well 12B is silicon, the second metallic material may comprise one of Ru, Pd, Pt, Co, Ni, TaₓAl_{y}N, WₓC_{y}N, a conductive metal oxide, and a combination thereof. Each value of x is independently from 0 to about 1 and each value of y is independently from 0 to about 1. In this case, if the semiconductor material of the first conductivity type well 12A is silicon also, the first metal portion 31 may comprise one of Zr, W, Ta, Hf, Ti, Al, a metal carbide, a transition metal aluminide, and a combination thereof.

In both embodiments, each of the first transistor in the first device region 100A and the second transistor in the second device region 100B is provided with a metal gate material that matches the type of the transistor. In one embodiment, the first transistor in the first device region 100A is a p-type field effect transistor and the second transistor in the second device region 100B is an n-type field effect transistor. The first metal portion 31 within the first electrode, which comprises the first metal portion 31 and the fourth metal portion 64, provides a work function, corresponding the first metallic material of the first metal portion 31, between the valence band edge of the semiconductor material of the first conductivity type well 12A and the mid-band-gap energy level of the semiconductor material of the first conductivity type well 12A, and preferably, close to the valence band edge of the semiconductor material of the first conductivity type well 12A. The third metal portion 63, which comprises the electrode of the second transistor, provides a work function, corresponding the second metallic material of the third metal portion 63, between the conduction band edge of the semiconductor material of the second conductivity type well 12B and the mid-band-gap energy level of the semiconductor material of the second conductivity type well 12B, and preferably, close to the conduction band edge of the semiconductor material of the second conductivity type well 12B.

In an alternate embodiment, the first transistor in the first device region 100A is an n-type field effect transistor and the second transistor in the second device region 100B is a p-type field effect transistor. The first metal portion 31 within the first electrode, which comprises the first metal portion 31 and the fourth metal portion 64, provides a work function, corresponding the first metallic material of the first metal portion 31, between the conduction band edge of the semiconductor material of the first conductivity type well 12A and the mid-band-gap energy level of the semiconductor material of the first conductivity type well 12A, and preferably, close to the conduction band edge of the semiconductor material of the first conductivity type well 12A. The third metal portion 63, which comprises the electrode of the second transistor, provides a work function, corresponding the second metallic material of the third metal portion 63, between the valence band edge of the semiconductor material of the second conductivity type well 12B and the mid-band-gap energy level of the semiconductor material of the second conductivity type well 12B, and preferably, close to the valence band edge of the semiconductor material of the second conductivity type well 12B.

In a yet alternate embodiment, the first transistor in the first device region 100A and the second transistor in the second device region 100B are the same type of field effect transistors but have different device characteristics such as different threshold voltages. For example, the first metal portion 31 provides a first work function and the third metal portion 63 provides a second work function different from the first work function of the first metal portion 31, resulting in the first transistor in the first device region 100A having a first threshold voltage and the second transistor in the second device region 100B having a second threshold voltage that is different from the first threshold voltage of the first transistor. In one variation, the work function of the first metal portion 31 may be close to the conduction band edge or valence band edge of the semiconductor material of the first conductivity type well 12A while the work function of the third metal portion 63 may be close to the mid-band-gap energy level of the semiconductor material of the first conductivity type well 12B. In another variation, the work function of the first metal portion 31 may be close to the mid-band-gap energy level of the semiconductor material of the first conductivity type well 12A while the work function of the third metal portion 63 may be close to the conduction band edge or valence band edge of the semiconductor material of the first conductivity type well 12B.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor structure comprising a first gate stack and a second gate stack located on a semiconductor substrate, wherein said first gate stack comprises a first gate dielectric vertically abutting said semiconductor substrate, a first metal portion vertically abutting said first gate dielectric and comprising a first metallic material, and a second metal portion vertically abutting said first metal portion and comprising a second metallic material which is different from said first metallic material, and wherein said second gate stack comprises a second gate dielectric vertically abutting said semiconductor substrate and a third metal portion vertically abutting said second gate dielectric and comprising said second metallic material.

2. The semiconductor structure of claim 1, wherein said first metal portion has a first thickness, said second metal portion has a second thickness, and said third metal portion has a third thickness, wherein the sum of said first thickness and said second thickness is substantially equal to said third thickness.

3. The semiconductor structure of claim 1, wherein a top surface of said second metal portion and a top surface of said third metal portion are substantially coplanar.

4. The semiconductor structure of claim 1, wherein said first gate dielectric and said second gate dielectric have a same composition.

5. The semiconductor structure of claim 4, wherein said first gate dielectric and said second gate dielectric comprise a material comprises one of HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂ONy, TiOₓN_{y}, SrTiOₓN_{y}, LaAlOₓN_{y}, Y₂OₓN_{y}, a silicate thereof, an alloy thereof, and non-stoichiometric variants thereof, wherein each value of x is independently from about 0.5 to about 3 and each value of y is independently from 0 to about 2.

6. The semiconductor structure of claim 1, wherein said first metallic material has a work function between a valence band edge of a semiconductor material directly underneath said first gate dielectric and a mid-band-gap energy level of said semiconductor material.

7. The semiconductor structure of claim 6, wherein said semiconductor material is silicon, and wherein said first metallic material comprises one of Ru, Pd, Pt, Co, Ni, TaₓAl_{y}N, WₓC_{y}N, a conductive metal oxide, and a combination thereof, wherein each value of x is independently from 0 to about 1 and each value of y is independently from 0 to about 1.

8. The semiconductor structure of claim 1, wherein said second metallic material has a work function between a conduction band edge of a semiconductor material directly underneath said second gate dielectric and a mid-band-gap energy level of said semiconductor material.

9. The semiconductor structure of claim 9, wherein said semiconductor material is silicon, and wherein said second metallic material comprises one of Zr, W, Ta, Hf, Ti, Al, a metal carbide, a transition metal aluminide, and a combination thereof.

10. The semiconductor structure of claim 1, further comprising:
a first source region and a first drain region, each having a doping of a first conductivity type, abutting said first gate dielectric, located in said semiconductor substrate, and separated from each other; and
a second source region and a second drain region, each having a doping of a second conductivity type, abutting said second gate dielectric, located in said semiconductor substrate, and separated from each other, and separated from said first source region and said first drain region, wherein said second conductivity type is the opposite type of said first conductivity type.

11. The semiconductor structure of claim 10, further comprising:
a first source side metal semiconductor alloy vertically abutting said first source region;
a first drain side metal semiconductor alloy vertically abutting said first drain region;
a second source side metal semiconductor alloy vertically abutting said second source region; and
a second drain side metal semiconductor alloy vertically abutting said second drain region.

12. The semiconductor structure of claim 1, further comprising a dielectric material layer abutting said semiconductor substrate and having a top surface which is substantially coplanar with a top surface of said second metal portion and a top surface of said third metal portion.

13. A method of forming a semiconductor structure comprising:
forming a first dummy gate structure and a second dummy gate structure on a semiconductor substrate, wherein said first dummy gate structure includes a stack of a first gate dielectric, a first metal portion comprising a first metallic material, and a first disposable material portion from bottom to top in that order and said second dummy gate structure includes a stack of a second gate dielectric, a second metal portion comprising said first metallic material, and a second disposable material portion from bottom to top in that order;
removing said second disposable material portion and said second metal portion, while preserving said second gate dielectric and said first disposable material portion;
removing said first disposable material portion, while preserving said first metal portion; and
forming a third metal portion directly on said second gate dielectric and a fourth metal portion directly on said first metal portion, wherein said third metal portion and said fourth metal portion comprise a second metallic material.

14. The method of claim 13, wherein said first metallic material and said second metallic material are different from each other.

15. The method of claim 13, further comprising:
forming a gate dielectric layer directly on said semiconductor substrate;
forming a first metal layer directly on said gate dielectric layer; and
forming a disposable material layer directly on said first metal layer, wherein said first and second gate dielectrics are formed by patterning of said gate dielectric layer, wherein said first and second metal portions are formed by patterning of said first metal layer, and wherein said first and second disposable material portions are formed by patterning of said disposable material layer.

16. The method of claim 13, further comprising:
depositing a dielectric material layer over said first dummy gate structure, said second dummy gate structure, and said semiconductor substrate; and
planarizing said dielectric material layer, wherein a top surface of said first dummy gate structure and a top surface of said second dummy gate structure are substantially coplanar with a top surface of said dielectric material layer after said planarizing.

17. The method of claim 16, wherein said first dummy gate structure includes a first dielectric cap and said second dummy gate structure includes a second dielectric cap, and wherein said method further comprises removing said first and second dielectric cap during said planarizing.

18. The method of claim 13, further comprising:
forming a first source region and a first drain region prior to removal of said first disposable material portion and said first metal portion, wherein each of said first source region and said first drain region has a doping of a first conductivity type, abuts said first gate dielectric, is located in said semiconductor substrate, and is separated from each other; and
forming a second source region and a second drain region prior to said removal of said first disposable material portion and said first metal portion, wherein each of said second source region and said second drain region has a doping of a second conductivity type, abuts said second gate dielectric, is located in said semiconductor substrate, and is separated from each other, and wherein said second conductivity type is the opposite type of said first conductivity type.

19. The method of claim 18, further comprising forming a first source side metal semiconductor alloy, a first drain side metal semiconductor alloy, a second source side metal semiconductor alloy, and a second drain side metal semiconductor alloy prior to said removal of said first disposable material portion and said first metal portion, wherein said first source side metal semiconductor alloy is formed directly on said first source region, said first drain side metal semiconductor alloy is formed directly on said first drain region, said second source side metal semiconductor alloy is formed directly on said second source region, and said second drain side metal semiconductor alloy is formed directly on said second drain region.

20. The method of claim 16, further comprising:
depositing a second metal layer on said second gate dielectric and said first metal portion; and
removing portions of said second metal layer above said dielectric material layer, wherein said third metal portion and said fourth metal portions are remaining portions of said second metal layer after said removing.
